(19) United States
(12) Patent Application Publication
(10) Pub. No.: US 2024/0055355 A1
(43) Pub. Date: Feb. 15, 2024

(54) SEMICONDUCTOR APPARATUS

(71) Applicant: ROHM CO., LTD., Kyoto-shi (JP)

(72) Inventors: Ryuta WATANABE, Kyoto-shi (JP); Takukazu OTSUKA, Kyoto-shi (JP)

(21) Appl. No.: 18/493,325

(22) Filed: Oct. 24, 2023

Related U.S. Application Data
(63) Continuation of application No. PCT/JP2022/021486, filed on May 26, 2022.

(30) Foreign Application Priority Data
Jun. 11, 2021 (JP) 2021-098152

(51) Int. Cl. H01L 23/538; H01L 23/31; H01L 23/34

(52) U.S. Cl. CPC H01L 23/5383; H01L 23/3121; H01L 23/34; H01L 2224/40155; H01L 24/40

(57) ABSTRACT

A semiconductor device includes an insulation layer, a support layer located on the insulation layer and containing a metal, and a semiconductor element bonded to the support layer. The semiconductor element includes an element metal layer facing the support layer. A solid-phase diffusion bonding layer is interposed between the support layer and the element metal layer. The insulation layer is lower in Vickers hardness than the support layer.

### TECHNICAL FIELD

The present disclosure relates to a semiconductor device including a semiconductor element bonded to a support layer containing a metal element in its composition.

### BACKGROUND ART

JP-A-2016-162773 discloses an example of a semiconductor device (power module) in which a plurality of semiconductor elements are bonded to a conductor layer. The plurality of semiconductor elements are bonded to the conductor layer, via a solder layer. Accordingly, when the semiconductor device is in use, the heat from the plurality of semiconductor elements is transmitted to the conductor layer, via the solder layer.

In the semiconductor device according to JP-A-2016-162773, however, it has been confirmed that the heat dissipation performance from a bonding interface, intermediating between the conductor layer and the plurality of semiconductor elements (interface between the conductive layer and the solder layer, and interface between the solder layer and the plurality of semiconductor elements), is degraded by a long-term use. Therefore, there is a demand for a measure to stabilize the heat dissipation performance from such bonding interface over a long period of time, to improve the reliability of the semiconductor device.

### BRIEF DESCRIPTION OF DRAWINGS

FIG. 1 is a perspective view showing a semiconductor device according to a first embodiment of the present disclosure.

FIG. 2 is a plan view of the semiconductor device shown in FIG. 1.

FIG. 3 is a plan view of the semiconductor device shown in FIG. 1, seen through a sealing resin.

FIG. 4 is a front view of the semiconductor device shown in FIG. 1.

FIG. 5 is a right-side view of the semiconductor device shown in FIG. 1.

FIG. 6 is a left-side view of the semiconductor device shown in FIG. 1.

FIG. 7 is a bottom view of the semiconductor device shown in FIG. 1.

FIG. 8 is a partially enlarged plan view from FIG. 3.

FIG. 9 is another partially enlarged plan view from FIG. 3.

FIG. 10 is a cross-sectional view taken along a line X-X in FIG. 3.

FIG. 11 is a cross-sectional view taken along a line XI-XI in FIG. 3.

FIG. 12 is a cross-sectional view taken along a line XII-XII in FIG. 3.

FIG. 13 is a cross-sectional view taken along a line XIII-XIII in FIG. 3.

FIG. 14 is a partially enlarged plan view from FIG. 8.

FIG. 15 is a cross-sectional view taken along a line XV-XV in FIG. 14.

FIG. 16 is a partially enlarged cross-sectional view from FIG. 15.

FIG. 17 is another partially enlarged plan view from FIG. 8.

FIG. 18 is a cross-sectional view taken along a line XVIII-XVIII in FIG. 17.

FIG. 19 is a partially enlarged cross-sectional view of a variation of the semiconductor device shown in FIG. 1.

FIG. 20 is a partially enlarged cross-sectional view of a semiconductor device according to a second embodiment of the present disclosure.

FIG. 21 is a partially enlarged cross-sectional view from FIG. 20.

FIG. 22 is a partially enlarged cross-sectional view of a variation of the semiconductor device shown in FIG. 20.

FIG. 23 is a partially enlarged cross-sectional view of a semiconductor device according to a third embodiment of the present disclosure.

FIG. 24 is a partially enlarged cross-sectional view from FIG. 23.

FIG. 25 is a partially enlarged cross-sectional view of a semiconductor device according to a fourth embodiment of the present disclosure.

FIG. 26 is a partially enlarged cross-sectional view from FIG. 25.

### DETAILED DESCRIPTION OF EMBODIMENTS

Hereafter, embodiments of the present disclosure will be described, with reference to the accompanying drawings.

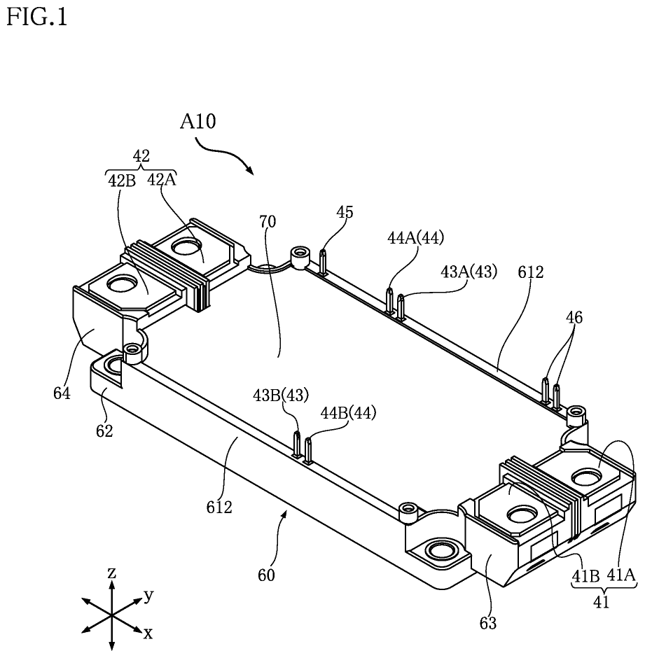

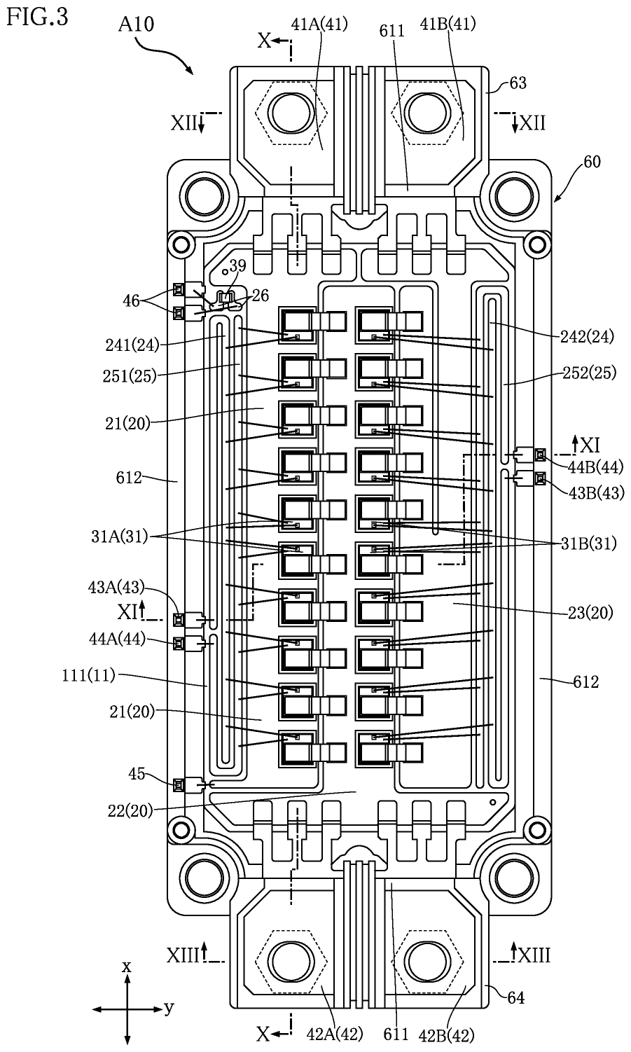

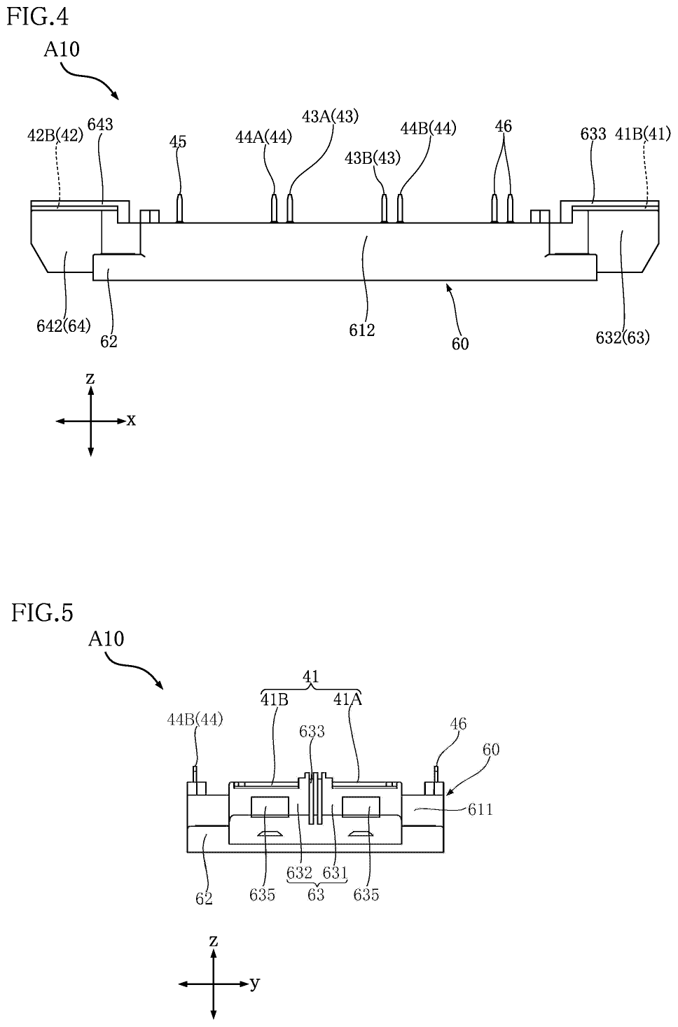

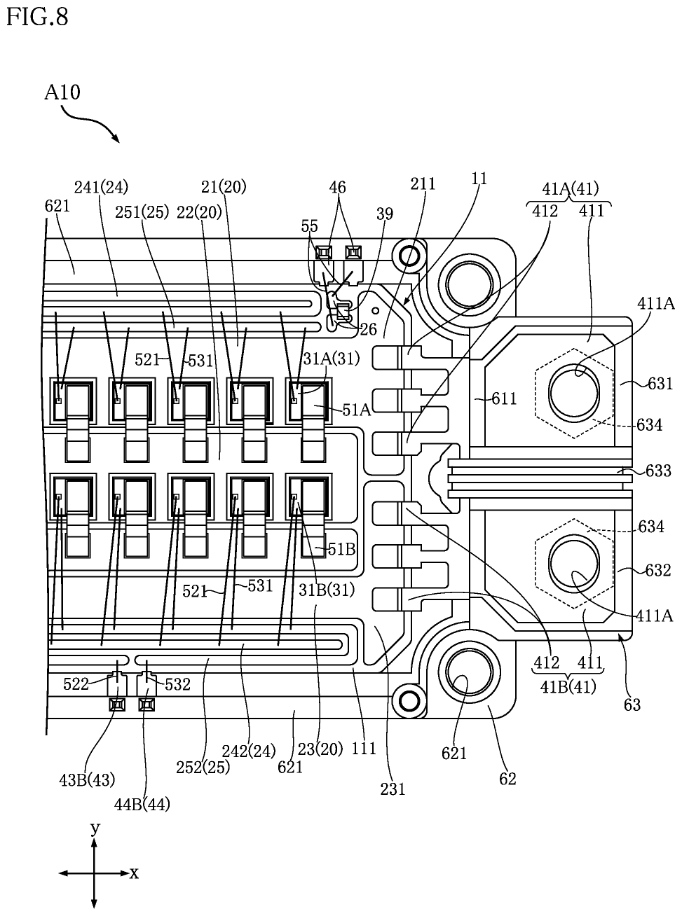

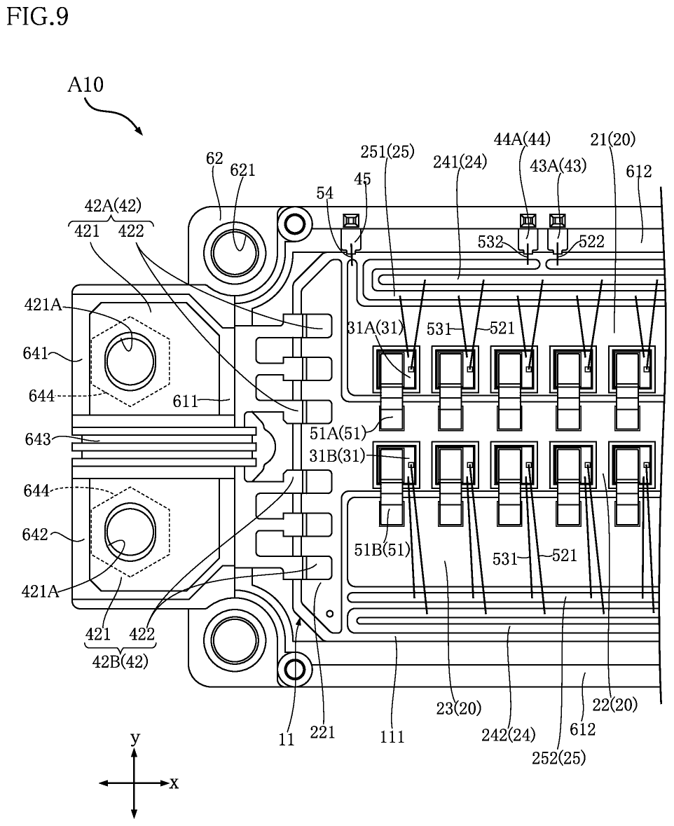

Referring to FIG. 1 to FIG. 18, a semiconductor device A10 according to a first embodiment of the present disclosure will be described hereunder. The semiconductor device A10 includes an insulation layer 11, a heat dissipation layer 12, a plurality of support layers 20, a plurality of input terminals 41, an output terminal 42, a plurality of semiconductor elements 31, a plurality of buffer layers 32, and a sealing resin 70. The semiconductor device A10 also includes a plurality of gate wirings 24, a plurality of detection wirings 25, a plurality of gate terminals 43, a plurality of detect terminals 44, and a case 60. FIG. 3, FIG. 8, and FIG. 9 each represent a view seen through the sealing resin 70, for clarity. In FIG. 3, a line X-X and a line XI-XI are drawn in dash-dot lines.

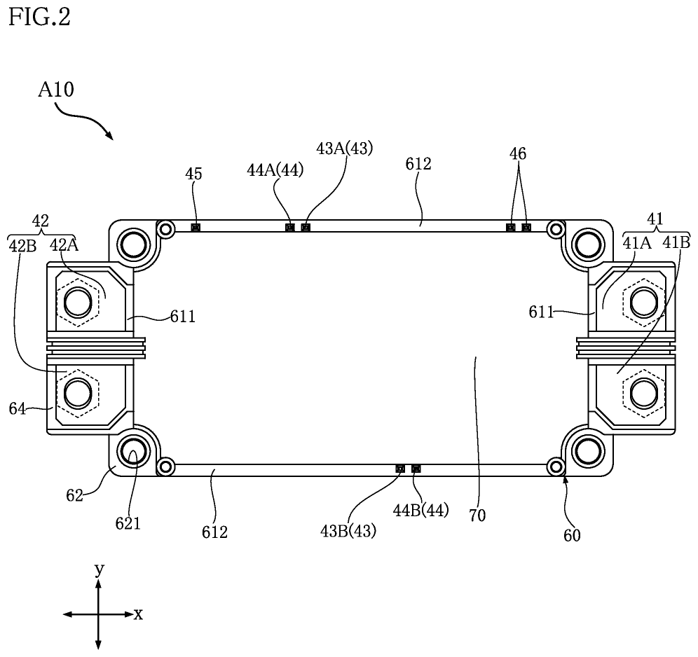

The semiconductor device A10 shown in FIG. 1 is configured as a power module. The semiconductor device A10 is used as an inverter for electrical appliances and hybrid vehicles. As shown in FIG. 1 and FIG. 2, the semiconductor device A10 has a generally rectangular shape, as viewed in a thickness direction z. The thickness direction z herein refers to the direction along the thickness of the insulation layer 11. Hereinafter, for convenience in description, a direction orthogonal to the thickness direction z will be defined as first direction x. a direction orthogonal to both of the thickness direction z and the first direction x will be defined as second direction y. Although the semiconductor device A10 is relatively elongate along the first direction x, the present disclosure is not limited to such a configuration.

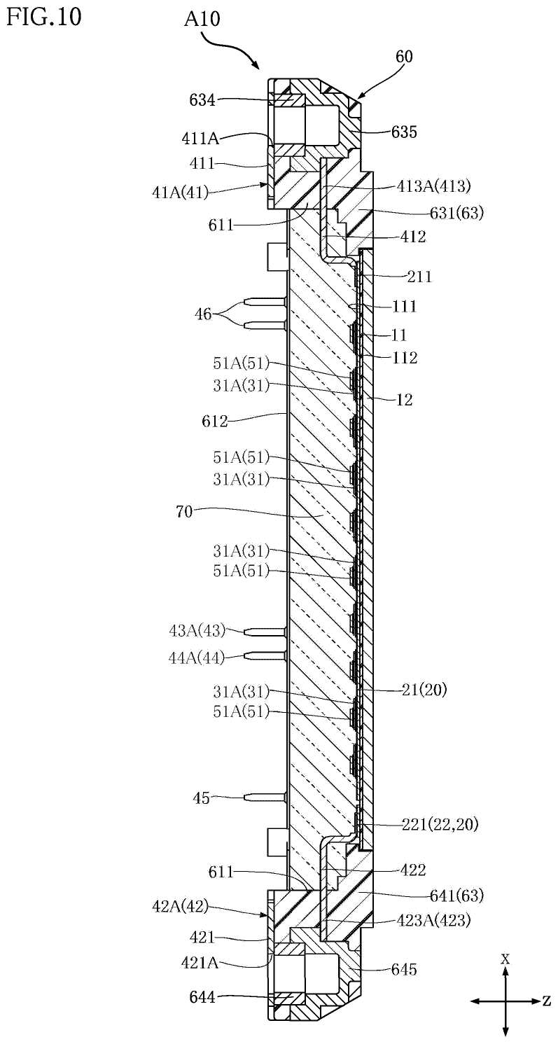

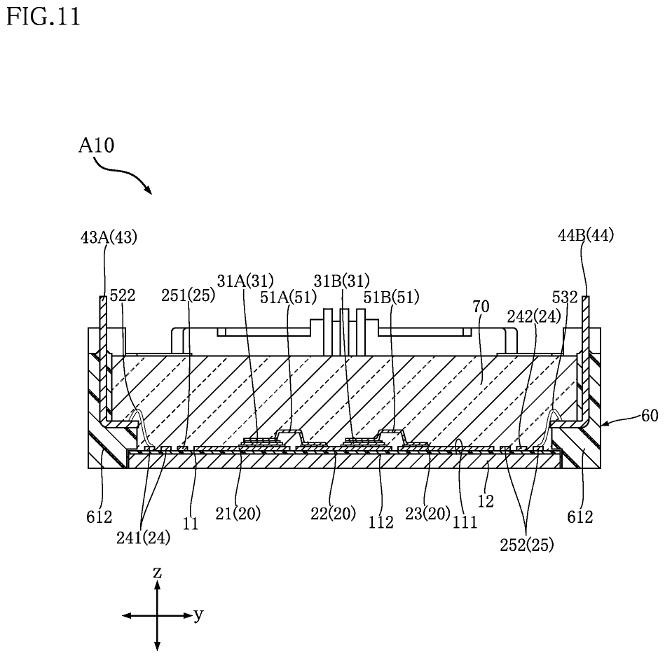

The insulation layer 11 is, as shown in FIG. 10 and FIG. 11, supported by the heat dissipation layer 12. The insulation layer 11 includes an obverse face 111 and a reverse face 112, oriented to opposite sides to each other, in the thickness direction z. The obverse face 111 is opposed to or faces the plurality of support layers 20. The reverse face 112 is opposed to the heat dissipation layer 12.

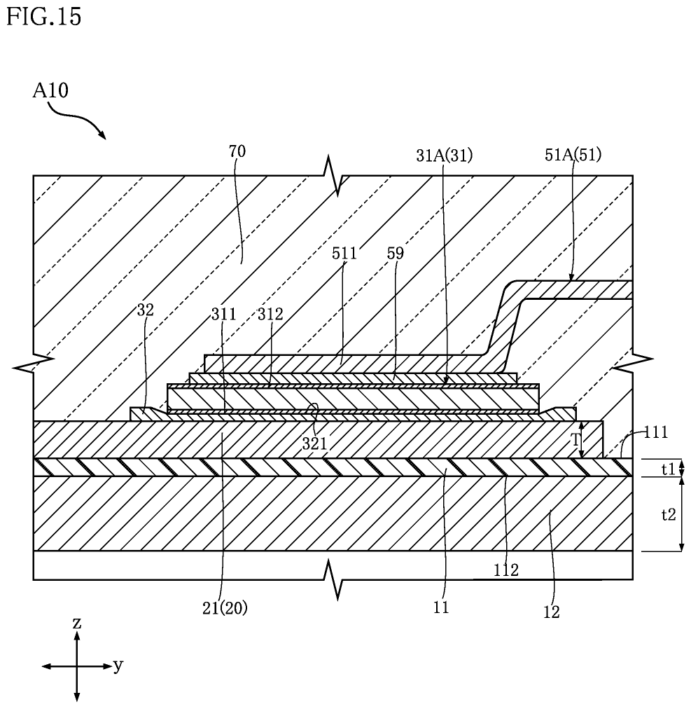

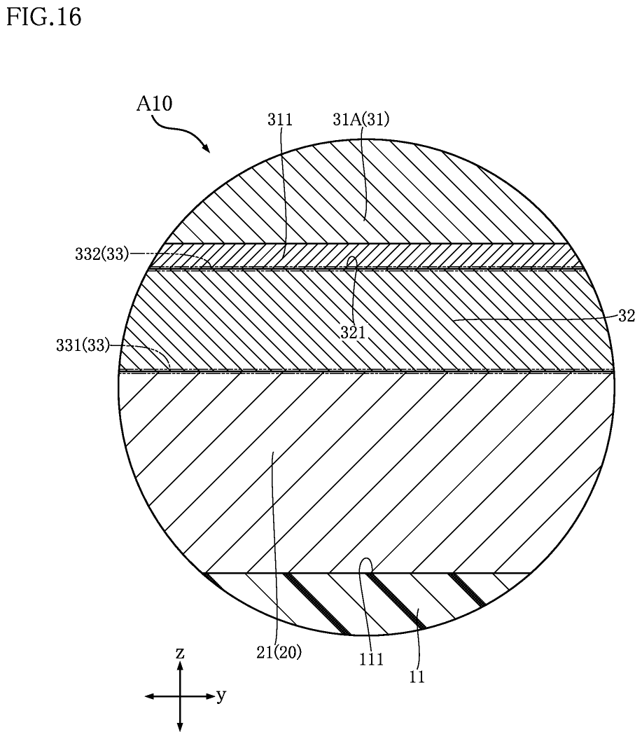

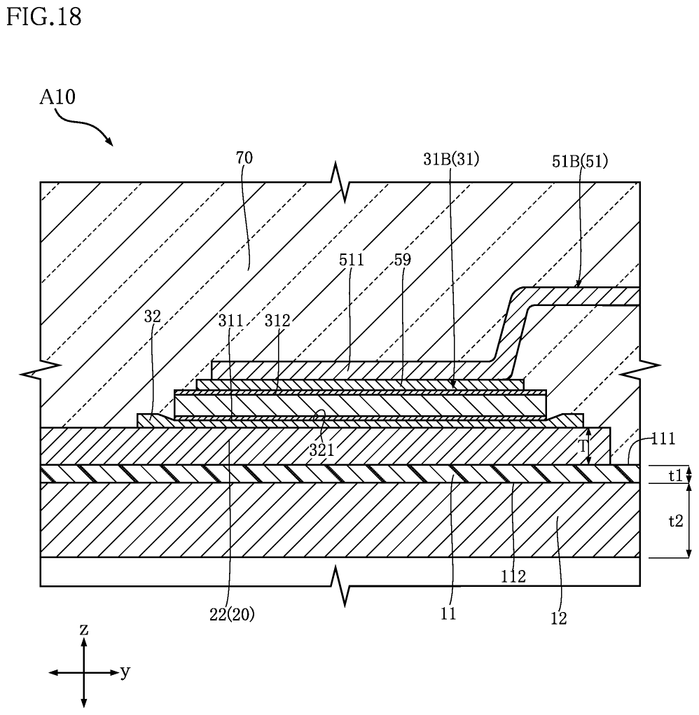

The insulation layer 11 contains a resin. The resin is, for example, an epoxy resin. The insulation layer 11 is lower in Vickers hardness (HV), than each of the plurality of support layers 20. As shown in FIG. 15 and FIG. 18, a thickness t1 of the insulation layer 11 is smaller than a thickness T of each of the plurality of support layers 20.

The heat dissipation layer 12 is, as shown in FIG. 10 and FIG. 11, located on the opposite side of the plurality of support layers 20 in the thickness direction z, across the insulation layer 11. As shown in FIG. 7, a part of the heat dissipation layer 12 is exposed to outside of the semiconductor device A10. In general, the semiconductor device A10 is mounted on a heatsink. The part of the heat dissipation layer 12 exposed to outside of the semiconductor device A10 is to oppose the heatsink. The main component of the heat dissipation layer 12 may be a flat metal plate. The composition of the metal plate includes copper. In other words, the metal plate contains copper. The surface of the heat dissipation layer 12 may be plated with nickel. A thickness t2 of the heat dissipation layer 12 is equal to or thicker than a thickness T of each of the plurality of support layers 20. Therefore, the thickness t2 of the heat dissipation layer 12 is thicker than the thickness t1 of the insulation layer 11.

The plurality of support layers 20 are, as shown in FIG. 3, located on the obverse face 111 of the insulation layer 11. The composition of the plurality of support layers 20 includes metal elements. The metal elements include copper. The thickness T of each of the plurality of support layers 20, shown in FIG. 15 and FIG. 18, is between once as thick and 60 times as thick, both ends inclusive, as the thickness t1 of the insulation layer 11. The plurality of support layers 20 include a first support layer 21, a second support layer 22, and a third support layer 23.

As shown in FIG. 3, the first support layer 21, the second support layer 22, and the third support layer 23 each extend in the first direction x. The second support layer 22 is located adjacent to the first support layer 21, in the second direction y. The third support layer 23 is located on the opposite side of the first support layer 21 in the second direction y, across the second support layer 22.

The plurality of gate wirings 24 are, as shown in FIG. 3, located on the obverse face 111 of the insulation layer 11. The plurality of gate wirings 24 include a first gate wiring 241 and a second gate wiring 242. The first gate wiring 241 is located on the opposite side of the second support layer 22 in the second direction y, across the first support layer 21. The first gate wiring 241 extends in the first direction x. The first gate wiring 241 includes two regions spaced from each other in the second direction y. Respective end portions of the two regions of the first gate wiring 241, located closest to the plurality of input terminals 41, are connected to each other. The second gate wiring 242 is located on the opposite side of the second support layer 22 in the second direction y, across the third support layer 23. The second gate wiring 242 extends in the first direction x. The second gate wiring 242 includes two regions spaced from each other in the second direction y. Respective end portions of the two regions of the second gate wiring 242, located closest to the output terminal 42, are connected to each other.

The plurality of detection wirings 25 are, as shown in FIG. 3, located on the obverse face 111 of the insulation layer 11. The plurality of detection wirings 25 include a first detection wiring 251 and a second detection wiring 252. The first detection wiring 251 is located adjacent to the first gate wiring 241, in the second direction y. The first detection wiring 251 extends in the first direction x. The first detection wiring 251 includes two regions spaced from each other in the second direction y. Respective end portions of the two regions of the first detection wiring 251, located closest to the output terminal 42, are connected to each other. The second detection wiring 252 is located adjacent to the second gate wiring 242, in the second direction y. The second detection wiring 252 extends in the first direction x. The second detection wiring 252 includes two regions spaced from each other in the second direction y. Respective end portions of the two regions of the second detection wiring 252, located closest to the plurality of input terminals 41, are connected to each other.

As shown in FIG. 8, the semiconductor device A10 includes a pair of pads 26. The pair of pads 26 are located adjacent to each other, in the first direction x. The pair of pads 26 are located at a corner of the insulation layer 11. The pair of pads 26 are located in the proximity of the first support layer 21.

The plurality of input terminals 41 each constitute, as shown in FIG. 2 and FIG. 3, a part of an external connection terminal provided on the semiconductor device A10. The plurality of input terminals 41 are connected to a DC power source located outside of the semiconductor device A10. The plurality of input terminals 41 are supported by the case 60. The plurality of input terminals 41 are each formed of a metal plate. For example, the metal plate contains copper. The thickness of the plurality of input terminals 41 is 1.0 mm.

The plurality of input terminals 41 include a first input terminal 41A and a second input terminal 41B. The first input terminal 41A is a positive electrode (P-terminal). The first input terminal 41A is bonded to a first pad part 211 of the first support layer 21. Accordingly, first input terminal 41A is electrically connected to the first support layer 21. The second input terminal 41B is a negative electrode (N-terminal). The second input terminal 41B is bonded to a third pad part 231 of the third support layer 23. Accordingly, the second input terminal 41B is electrically connected to the third support layer 23. The first input terminal 41A and the second input terminal 41B are located adjacent to each other, in the second direction y.

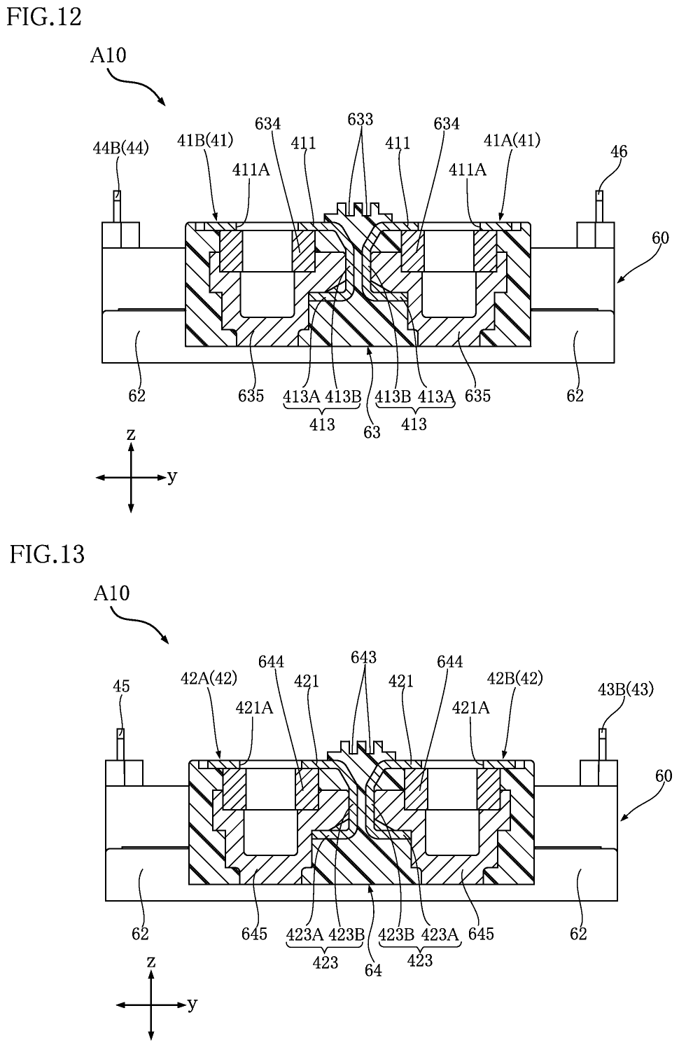

As shown in FIG. 8 and FIG. 12, the first input terminal 41A and the second input terminal 41B each include an external connect part 411, an internal connect part 412, and an intermediate part 413.

The external connect part 411 is formed in a flat plate shape, exposed from the semiconductor device A10 and oriented orthogonal to the thickness direction z. To the external connect part 411, for example a cable of the DC power source is connected. The external connect part 411 is supported by the case 60. The external connect part 411 includes a connect hole 411A penetrating therethrough in the thickness direction z. To the connect hole 411A, a fastening member such as a bolt is inserted. The surface of the external connect part 411 may be plated with nickel (Ni).

The internal connect part 412 is formed in a comb-teeth shape, and bonded to the first pad part 211 of the first support layer 21, in the first input terminal 41A, and to the third pad part 231 of the third support layer 23, in the second input terminal 41B. In the semiconductor device A10, the internal connect part 412 includes three teeth, which are aligned along the second direction y. The teeth are each bent in the thickness direction z. Accordingly, the teeth have a hook shape, as viewed in the second direction y. The teeth are each bonded to the first pad part 211 or third pad part 231, by ultrasonic welding.

The intermediate part 413 serves to connect the external connect part 411 and the internal connect part 412 to each other. The intermediate part 413 has an L-shaped cross-section, as viewed in the first direction x. The intermediate part 413 includes a base portion 413A and an upright portion 413B. The base portion 413A extends along the first direction x and the second direction y. An end portion of the base portion 413A in the first direction x is connected to the internal connect part 412. The upright portion 413B extends from the base portion 413A in the thickness direction z. An end portion of the upright portion 413B in the thickness direction z is connected to the external connect part 411.

The output terminal 42 constitutes, as shown in FIG. 2 and FIG. 3, a part of the external connection terminal provided on the semiconductor device A10. The output terminal 42 is connected, for example, to a load (e.g., a motor) prepared outside of the semiconductor device A10. The output terminal 42 is supported by the case 60, and located on the opposite side of the plurality of input terminals 41 in the first direction x, with respect to the insulation layer 11. The output terminal 42 is formed of a metal plate. For example, the metal plate contains copper. The thickness of the output terminal 42 is 1.0 mm.

In the semiconductor device A10, the output terminal 42 is divided in two sections, namely a first terminal part 42A and a second terminal part 42B. Alternatively, the output terminal 42 may be a single-piece component in which the first terminal part 42A and the second terminal part 42B are unified. The first terminal part 42A and the second terminal part 42B are bonded to the second pad part 221 of the second support layer 22. Accordingly, the output terminal 42 is electrically connected to the second support layer 22. The first terminal part 42A and the second terminal part 42B are located adjacent to each other, in the second direction y.

As shown in FIG. 9 and FIG. 13, the first terminal part 42A and the second terminal part 42B each include an external connect part 421, an internal connect part 422, and an intermediate part 423.

The external connect part 421 is formed in a flat plate shape, exposed from the semiconductor device A10 and oriented orthogonal to the thickness direction z. To the external connect part 421, for example a cable electrically connected to a load is connected. The external connect part 421 is supported by the case 60. The external connect part 421 includes a connect hole 421A penetrating therethrough in the thickness direction z. To the connect hole 421A, a fastening member such as a bolt is inserted. The surface of the external connect part 421 may be plated with nickel.

The internal connect part 422 is formed in a comb-teeth shape, and bonded to the second pad part 221 of the second support layer 22. In the semiconductor device A10, the internal connect part 412 includes three teeth, which are aligned along the second direction y. The teeth are each bent in the thickness direction z. Accordingly, the teeth have a hook shape, as viewed in the second direction y. The teeth are each bonded to the second pad part 221, by ultrasonic welding.

The intermediate part 423 serves to connect the external connect part 421 and the internal connect part 422 to each other. The intermediate part 423 has an L-shaped cross-section, as viewed in the first direction x. The intermediate part 423 includes a base portion 423A and an upright portion 423B. The base portion 423A extends along the first direction x and the second direction y. An end portion of the base portion 423A in the first direction x is connected to the internal connect part 422. The upright portion 423B extends from the base portion 423A in the thickness direction z. An end portion of the upright portion 423B in the thickness direction z is connected to the external connect part 421.

AC voltages of various frequencies are outputted from the output terminal 42, when DC voltages are applied to the first input terminal 41A and the second input terminal 41B of the input terminal 41, so that the plurality of semiconductor elements 31 are driven. Such AC voltage is supplied to a load, such as a motor.

The plurality of gate terminals 43 each constitute, as shown in FIG. 2 to FIG. 4, a part of the external connection terminal provided on the semiconductor device A10. The plurality of gate terminals 43 are electrically connected to the respective gate wirings 24. The plurality of gate terminals 43 are bonded to a drive circuit (e.g., a gate driver) for the semiconductor device A10, located outside. The plurality of gate terminals 43 are supported by the case 60. The plurality of gate terminals 43 are each constituted of a metal bar. For example, the metal bar contains copper. The surface of each of the plurality of gate terminals 43 may be plated with tin, or nickel and tin. As shown in FIG. 11, the plurality of gate terminals 43 each have an L-shaped cross-section, as viewed in the first direction x. A part of each of the plurality of gate terminals 43 is protruding from the case 60 in the thickness direction z, to the side to which the obverse face 111 of the insulation layer 11 is oriented.

The plurality of gate terminals 43 include a first gate terminal 43A and a second gate terminal 43B. The first gate terminal 43A is, as shown in FIG. 9, located in the proximity of the first gate wiring 241, in the second direction y. The second gate terminal 43B is, as shown in FIG. 8, located on the opposite side of the first gate terminal 43A in the second direction y, with respect to the insulation layer 11. The second gate terminal 43B is located in the proximity of the second gate wiring 242.

The plurality of detect terminals 44 each constitute, as shown in FIG. 2 to FIG. 4, a part of the external connection terminal provided on the semiconductor device A10. The plurality of detect terminals 44 are electrically connected to the respective detection wirings 25. The plurality of detect terminals 44 are each bonded to a control circuit for the semiconductor device A10, located outside. The plurality of detect terminals 44 are supported by the case 60. The plurality of detect terminals 44 are each constituted of a metal bar. For example, the metal bar contains copper. The surface of each of the plurality of detect terminals 44 may be plated with tin, or nickel and tin. As shown in FIG. 11, the plurality of detect terminals 44 each have an L-shaped cross-section, as viewed in the first direction x. A part of each of the plurality of detect terminals 44 is protruding from the case 60 in the thickness direction z, to the side to which the obverse face 111 of the insulation layer 11 is oriented.

The plurality of detect terminals 44 include a first detect terminal 44A and a second detect terminal 44B. The first detect terminal 44A is, as shown in FIG. 9, located adjacent to the first gate terminal 43A, in the first direction x. The second detect terminal 44B is, as shown in FIG. 8, located adjacent to the second gate terminal 43B, in the first direction x.

As shown in FIG. 2 to FIG. 4, and FIG. 9, the semiconductor device A10 includes an input current detect terminal 45. The input current detect terminal 45 constitutes a part of the external connection terminal provided on the semiconductor device A10. The input current detect terminal 45 is connected to a control circuit for the semiconductor device A10, located outside. The input current detect terminal 45 is supported by the case 60. The input current detect terminal 45 is constituted of a metal bar. For example, the metal bar contains copper. The surface of the input current detect terminal 45 may be plated with tin, or nickel and tin. The input current detect terminal 45 has the same shape as the plurality of gate terminals 43 shown in FIG. 11. A part of the input current detect terminal 45 is, like the plurality of gate terminals 43 shown in FIG. 11, protruding from the case 60 in the thickness direction z, to the side to which the obverse face 111 of the insulation layer 11 is oriented. The input current detect terminal 45 is located at the same position as the first gate terminal 43A, in the second direction y. The input current detect terminal 45 is spaced from the first gate terminal 43A in the first direction x, to the side on which the output terminal 42 is located.

As shown in FIG. 9, the semiconductor device A10 includes an input current detect wire 54. The input current detect wire 54 is bonded to the input current detect terminal 45 and the first support layer 21. Accordingly, the input current detect terminal 45 is electrically connected to the first support layer 21. The input current detect wire 54 is, for example, formed of aluminum (Al).

As shown in FIG. 2 to FIG. 4, and FIG. 8, the semiconductor device A10 includes a pair of thermistor terminals 46. The pair of thermistor terminals 46 constitute a part of the external connection terminal provided on the semiconductor device A10. The pair of thermistor terminals 46 are connected to a control circuit for the semiconductor device A10, located outside. The pair of thermistor terminals 46 are supported by the case 60. The pair of thermistor terminals 46 are each constituted of a metal bar which, for example, contains copper. The surface of each of the pair of thermistor terminals 46 may be plated with tin, or with nickel and tin. The shape of each of the thermistor terminals 46 is the same as that of the plurality of gate terminals 43 shown in FIG. 11. A part of each of the thermistor terminals 46 is, like the plurality of gate terminals 43 shown in FIG. 11, protruding from the case 60 in the thickness direction z, to the side to which the obverse face 111 of the insulation layer 11 is oriented. The pair of thermistor terminals 46 are located at the same position as the first gate terminal 43A, in the second direction y. The pair of thermistor terminals 46 are spaced from the first gate terminal 43A in the first direction x, to the side on which the plurality of input terminals 41 are located. The pair of thermistor terminals 46 are located adjacent to each other, in the first direction x.

As shown in FIG. 8, the semiconductor device A10 includes a pair of thermistor wires 55. The pair of thermistor wires 55 are respectively bonded to the pair of thermistor terminals 46, and the pair of pads 26. Accordingly, the pair of input current detect terminals 45 are electrically connected to the pair of pads 26. The pair of thermistor wires 55 are, for example, formed of aluminum.

The plurality of semiconductor elements 31 are, as shown in FIG. 3, bonded to the first support layer 21 and the second support layer 22, of the plurality of support layers 20. The plurality of semiconductor elements 31 include a plurality of first semiconductor elements 31A, and a plurality of second semiconductor elements 31B. The plurality of first semiconductor elements 31A are bonded to the first support layer 21, and aligned along the first direction x. The plurality of second semiconductor elements 31B are bonded to the second support layer 22, and aligned along the first direction x. The plurality of semiconductor elements 31 are each constituted as a metal-oxide-semiconductor field-effect transistor (MOSFET), whose main constituent may be silicon (Si) or silicon carbide (SiC). Alternatively, the plurality of semiconductor elements 31 may each be a switching element such as an insulated gate bipolar transistor (IGBT), or a diode. For the description of the semiconductor device A10, it will be assumed that the plurality of semiconductor elements 31 are the MOSFET of the n-channel type having a vertical structure. Accordingly, in the semiconductor device A10, the first support layer 21 and the second support layer 22 each constitute the conduction path to the plurality of semiconductor elements 31.

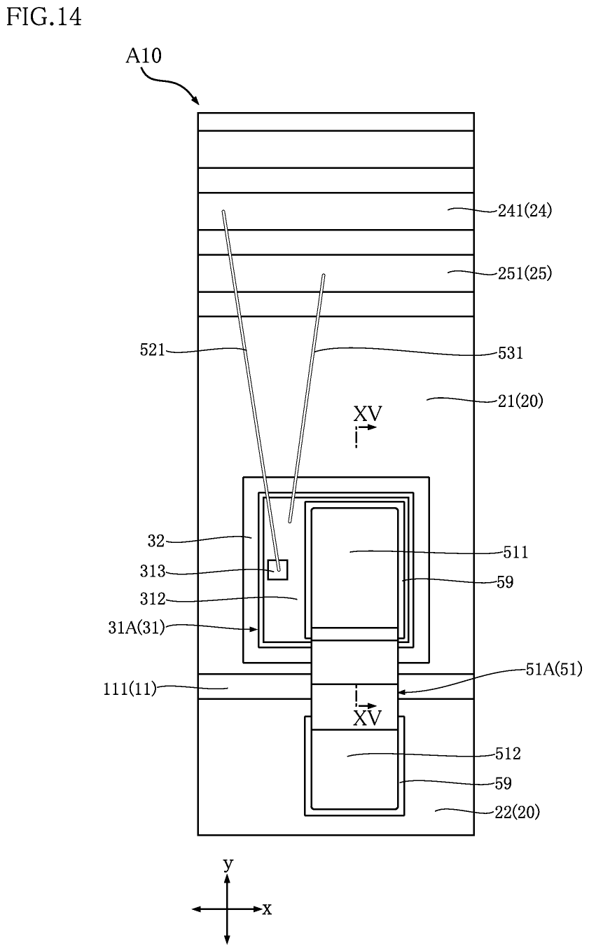

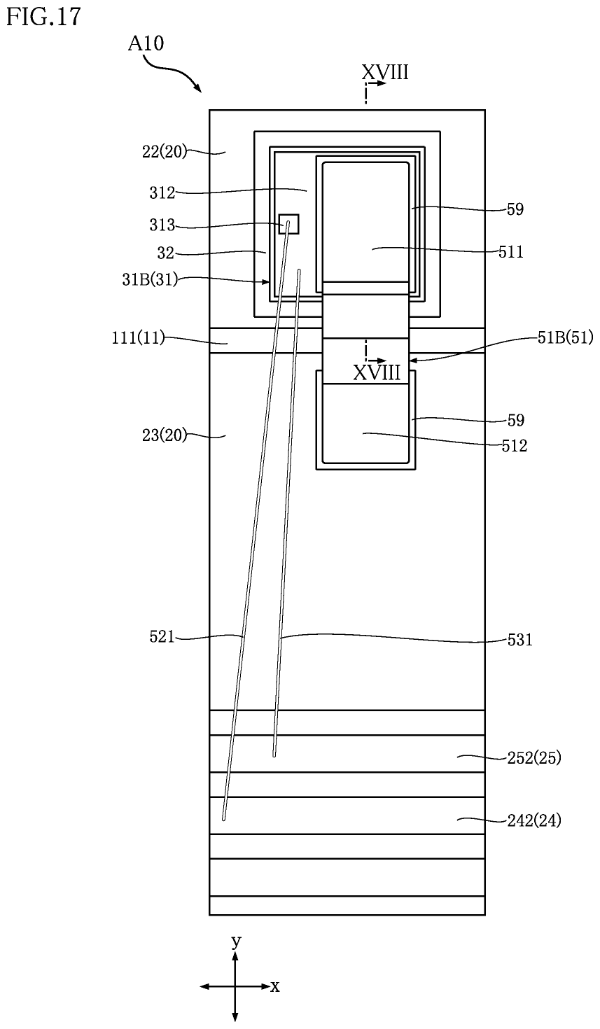

As shown in FIG. 14, FIG. 15, FIG. 17, and FIG. 18, the plurality of semiconductor elements 31 each include an element metal layer 311, a first electrode 312, and a second electrode 313.

As shown in FIG. 15 and FIG. 18, the element metal layer 311 is opposed to one of the first support layer 21 and the second support layer 22. The element metal layer 311 is electrically connected to a circuit formed on the semiconductor element 31. Therefore, the element metal layer 311 serves as an electrode of the semiconductor element 31. Alternatively, the element metal layer 311 may not serve as the electrode of the semiconductor element 31, as the case of a switching element of a horizontal structure. In this case, the first support layer 21 and the second support layer 22 do not constitute the conduction path to the plurality of semiconductor elements 31. To the element metal layer 311, a current corresponding to the power yet to be converted by the semiconductor element 31 is supplied. In other words, the element metal layer 311 corresponds to a drain electrode of the semiconductor element 31.

As shown in FIG. 15 and FIG. 18, the first electrode 312 is located on the opposite side of the element metal layer 311, in the thickness direction z. To the first electrode 312, a current corresponding to the power converted by the semiconductor element 31 is supplied. In other words, the first electrode 312 corresponds to a source electrode of the semiconductor element 31.

As shown in FIG. 14 and FIG. 17, the second electrode 313 is located on the same side as the first electrode 312, in the thickness direction z. To the second electrode 313, a gate voltage for driving the semiconductor element 31 is applied. In other words, the second electrode 313 corresponds to a gate electrode of the semiconductor element 31. The second electrode 313 is smaller in area than the first electrode 312, as viewed in the thickness direction z.

The buffer layer 32 is, as shown in FIG. 15 and FIG. 18, interposed between either of the first support layer 21 and the second support layer 22 of the plurality of support layers 20, and the element metal layer 311 of one of the plurality of semiconductor elements 31. The composition of the buffer layer 32 includes aluminum. The buffer layer 32 is lower in Vickers hardness, than each of the plurality of support layers 20. As shown in FIG. 14 and FIG. 17, the buffer layer 32 overlapping with one of the plurality of semiconductor elements 31 is protruding to the outer side of the corresponding semiconductor element 31, as viewed in the thickness direction z. Alternatively, the peripheral edge of the buffer layer 32 overlapping with one of the plurality of semiconductor elements 31 may coincide with the peripheral edge of the corresponding semiconductor element 31, or be surrounded by the peripheral edge of the semiconductor element 31, as viewed in the thickness direction z.

The element metal layer 311 of each of the plurality of semiconductor elements 31 is bonded to either of the first support layer 21 and the second support layer 22, by means of solid-phase diffusion. The solid-phase diffusion bonding is performed under a relatively high temperature and pressure. Accordingly, a solid-phase diffusion bonding layer 33 is interposed between either of the first support layer 21 and the second support layer 22 and the element metal layer 311, as shown in FIG. 16. The solid-phase diffusion bonding layer 33 represents a concept of a metal bonding layer, located at the interface between two metal layers, produced as result of the two metal layers in contact with each other having been bonded through the solid-phase diffusion. The solid-phase diffusion bonding layer 33 does not necessarily exist as a metal bonding layer having a definite thickness. The presence of the solid-phase diffusion bonding layer 33 may be able to be identified, in a form of a portion where an impurity or a void that was mixed in the process of the solid-phase diffusion remains along the interface between the two metal layers.

In the semiconductor device A10, the element metal layer 311 of each of the plurality of semiconductor elements 31 is bonded to either of the first support layer 21 and the second support layer 22 via the buffer layer 32, by means of solid-phase diffusion. Accordingly, the element metal layer 311 of each of the plurality of first semiconductor elements 31A is electrically connected to the first support layer 21. Therefore, the element metal layer 311 of each of the plurality of first semiconductor elements 31A is electrically connected to the first input terminal 41A. Likewise, the element metal layer 311 of each of the plurality of second semiconductor elements 31B is electrically connected to the second support layer 22. Therefore, the element metal layer 311 of each of the plurality of second semiconductor elements 31B is electrically connected to the output terminal 42.

As shown in FIG. 16, in the semiconductor device A10, the solid-phase diffusion bonding layer 33 incudes a first bonding layer 331 and a second bonding layer 332, spaced from each other in the thickness direction z. The first bonding layer 331 is interposed between either of the first support layer 21 and the second support layer 22, and the buffer layer 32. In the semiconductor device A10, the first bonding layer 331 is located along the interface between either of the first support layer 21 and the second support layer 22, and the buffer layer 32. The second bonding layer 332 is interposed between the buffer layer 32 and the element metal layer 311 of each of the plurality of semiconductor elements 31. In the semiconductor device A10, the second bonding layer 332 is located along the interface between the buffer layer 32 and the element metal layer 311.

As shown in FIG. 15 and FIG. 18, the buffer layer 32 includes a first recess 321, receding toward either of the first support layer 21 and the second support layer 22. The element metal layer 311 of each of the plurality of semiconductor elements 31 is overlapping with the first recess 321, as viewed in the thickness direction z. The first recess 321 is in contact with the sealing resin 70. The first recess 321 is a vestige resulting from the solid-phase diffusion bonding between the element metal layer 311 of each of the plurality of semiconductor elements 31 and either of the first support layer 21 and the second support layer 22.

The semiconductor device A10 includes a thermistor 39, as shown in FIG. 3 and FIG. 8. The thermistor 39 is bonded to the pair of pads 26. In the semiconductor device A10, the thermistor 39 is a negative temperature coefficient (NTC) thermistor. The NTC thermistor has a characteristic that the resistance gradually decreases, in response to an increase in temperature. The thermistor 39 is used as a temperature sensor in the semiconductor device A10. The thermistor 39 is electrically connected to the pair of thermistor terminals 46, via the pair of pads 26 and the pair of thermistor wires 55.

The semiconductor device A10 includes, as shown in FIG. 8 and FIG. 9, a plurality of conduction members 51, a plurality of first gate wires 521, and a plurality of first detect wires 531. These components are respectively bonded to the plurality of semiconductor elements 31. Each of the plurality of conduction members 51 is a metal clip. The composition of the plurality of conduction members 51 includes copper. Alternatively, the plurality of conduction members 51 may each include a plurality of wires. The plurality of first gate wires 521 and the plurality of first detect wire 531 are, for example, formed of aluminum.

As shown in FIG. 14 and FIG. 17, the plurality of conduction members 51 each include a first bonding portion 511 and a second bonding portion 512. The first bonding portion 511 is bonded to the first electrode 312 of one of the plurality of semiconductor elements 31, via a bonding layer 59. The bonding layer 59 is, for example, formed of solder. The second bonding portion 512 is bonded to either of the second support layer 22 and the third support layer 23 of the plurality of support layers 20, via the bonding layer 59.

As shown in FIG. 8 and FIG. 9, the plurality of conduction members 51 include a plurality of first conduction members 51A, and a plurality of second conduction members 51B. As shown in FIG. 14, the plurality of first conduction members 51A are bonded to the first electrode 312 and the second support layer 22 of the respective first semiconductor elements 31A. Accordingly, the first electrode 312 of each of the plurality of first semiconductor elements 31A is electrically connected to the second support layer 22. Therefore, the first electrode 312 of each of the plurality of first semiconductor elements 31A is electrically connected to the output terminal 42. As shown in FIG. 17, the plurality of second conduction members 51B are bonded to the first electrode 312 and the third support layer 23 of the respective second semiconductor elements 31B. Accordingly, the first electrode 312 of each of the plurality of semiconductor elements 31 is electrically connected to the third support layer 23. Therefore, the first electrode 312 of each of the plurality of second semiconductor elements 31B is electrically connected to the second input terminal 41B.

Referring to FIG. 14, the plurality of first gate wires 521 and the plurality of first detect wires 531, respectively bonded to the plurality of first semiconductor elements 31A, will be described hereunder. The plurality of first gate wires 521 are bonded to the second electrode 313 and the first gate wiring 241 of the respective first semiconductor elements 31A. The plurality of first detect wires 531 are bonded to the first electrode 312 and the first detection wiring 251 of the respective first semiconductor elements 31A.

Referring to FIG. 17, the plurality of first gate wires 521 and the plurality of first detect wires 531, respectively bonded to the plurality of second semiconductor elements 31B, will be described hereunder. The plurality of first gate wires 521 are bonded to the second electrode 313 and the second gate wiring 242 of the respective second semiconductor elements 31B. The plurality of first detect wires 531 are bonded to the first electrode 312 and the second detection wiring 252 of the respective second semiconductor elements 31B.

The semiconductor device A10 includes a pair of second gate wires 522, as shown in FIG. 8 and FIG. 9. The pair of second gate wires 522 are bonded to the plurality of gate terminals 43 and the plurality of gate wirings 24. The plurality of second gate wires 522 are, for example, formed of aluminum.

As shown in FIG. 9, one of the second gate wires 522 is bonded to the first gate terminal 43A and the first gate wiring 241. Accordingly, the first gate terminal 43A is electrically connected to the second electrode 313 of the plurality of first semiconductor elements 31A. As shown in FIG. 8, the other second gate wire 522 is bonded to the second gate terminal 43B and the second gate wiring 242. Accordingly, the second gate terminal 43B is electrically connected to the second electrode 313 of the plurality of second semiconductor elements 31B.

The semiconductor device A10 includes a pair of s second detect wires 532, as shown in FIG. 8 and FIG. 9. The pair of second detect wires 532 are bonded to the plurality of detect terminals 44 and the plurality of detection wirings 25. The plurality of second detect wires 532 are, for example, formed of aluminum.

As shown in FIG. 9, one of the second detect wires 532 is bonded to the first detect terminal 44A and the first detection wiring 251. Accordingly, the first detect terminal 44A is electrically connected to the first electrode 312 of the plurality of first semiconductor elements 31A. As shown in FIG. 8, the other second detect wire 532 is bonded to the second detect terminal 44B and the second detection wiring 252. Accordingly, the second detect terminal 44B is electrically connected to the first electrode 312 of the plurality of second semiconductor elements 31B.

As shown in FIG. 10 and FIG. 11, the case 60 supports the heat dissipation layer 12. The obverse face 111 of the insulation layer 11 is opposed to the case 60, in the thickness direction z. The case 60 is electrically insulative. The case 60 is formed of a material containing a highly heat-resistant resin, such as polyphenylene sulfide (PPS). The case 60 includes a pair of first sidewalls 611, a pair of second sidewalls 612, a plurality of mounting bases 62, an input terminal base 63, and an output terminal base 64.

As shown in FIG. 2 and FIG. 3, the pair of first sidewalls 611 are spaced from each other, in the first direction x. The pair of first sidewalls 611 each extend along the second direction y and the thickness direction z, and an end portion in the thickness direction z is in contact with the heat dissipation layer 12.

As shown in FIG. 2 and FIG. 3, the pair of second sidewalls 612 are spaced from each other, in the second direction y. The pair of second sidewalls 612 each extend along the first direction x and the thickness direction z, and an end portion in the thickness direction z is in contact with the heat dissipation layer 12. End portions of each of the pair of second sidewalls 612 in the first direction x are respectively connected to the pair of first sidewalls 611. Inside one of the second sidewalls 612, the first gate terminal 43A, and the pair of thermistor terminals 46 are located. Inside the other second sidewall 612, the second gate terminal 43B and the second detect terminal 44B are located. As shown in FIG. 8 and FIG. 9, the respective end portions of the mentioned terminals, located in the proximity of the insulation layer 11 in the thickness direction, are supported by the pair of second sidewalls 612.

As shown in FIG. 2, FIG. 8, and FIG. 9, the plurality of mounting bases 62 are respectively located at the four corners of the case 60, as viewed in the thickness direction z. The heat dissipation layer 12 is in contact with the respective lower faces of the plurality of mounting bases 62. The plurality of mounting bases 62 each include a mounting hole 621, penetrating therethrough in the thickness direction z. The semiconductor device A10 can be mounted on the heatsink, by inserting a fastening member such as a bolt, in each of the plurality of mounting holes 621.

As shown in FIG. 2, FIG. 5, and FIG. 8, the input terminal base 63 is protruding outward from one of the first sidewalls 611, in the first direction x. The input terminal base 63 serves to support the plurality of input terminals 41. The input terminal base 63 includes a first terminal base 631 and a second terminal base 632. The first terminal base 631 and the second terminal base 632 are spaced from each other, in the second direction y. The first terminal base 631 supports the first input terminal 41A. From the first terminal base 631, the external connect part 411 of the first input terminal 41A is exposed. The second terminal base 632 supports the second input terminal 41B. From the second terminal base 632, the external connect part 411 of the second input terminal 41B is exposed. A plurality of grooves 633 are formed so as to extend in the first direction x, between the first terminal base 631 and the second terminal base 632. As shown in FIG. 10 and FIG. 12, a pair of nuts 634 and a pair of intermediate members 635 are respectively provided inside the first terminal base 631 and the second terminal base 632. The pair of intermediate members 635 are located on the side of the insulation layer 11 in the thickness direction z with respect to the respective nuts 634, and in contact therewith. One of the intermediate members 635 supports the external connect part 411 and the intermediate part 413 of the first input terminal 41A. The other intermediate member 635 supports the external connect part 411 and the intermediate part 413 of the second input terminal 41B. A part of each of the pair of intermediate members 635 is exposed from the input terminal base 63. The pair of nuts 634 respectively correspond to the pair of connect holes 411A, formed in the first input terminal 41A and the second input terminal 41B. The fastening member such as a bolt, inserted in each of the pair of connect holes 411A, is screw-fitted with the corresponding nut 634.

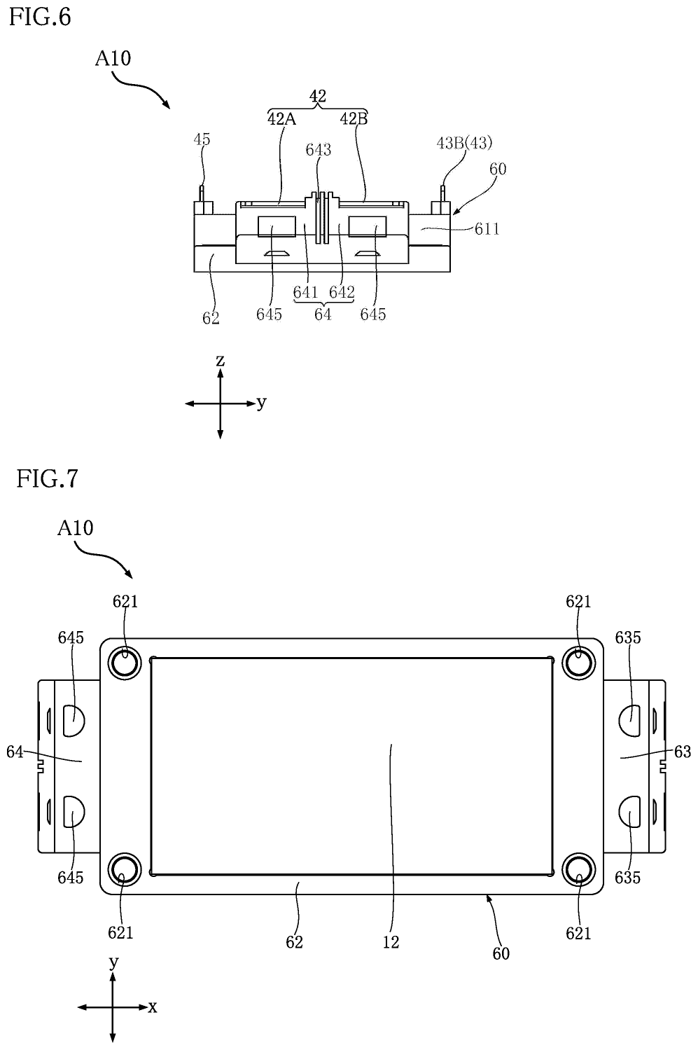

As shown in FIG. 2, FIG. 6, and FIG. 9, the output terminal base 64 is protruding outward from the other first sidewall 611, in the first direction x. The output terminal base 64 serves to support the output terminal 42. The output terminal base 64 includes a first terminal base 641 and a second terminal base 642. The first terminal base 641 and the second terminal base 642 are spaced from each other, in the second direction y. The first terminal base 641 supports the first terminal part 42A of the output terminal 42. From the first terminal base 641, the external connect part 421 of the second terminal part 42B is exposed. The second terminal base 642 supports the second terminal part 42B of the output terminal 42. From the second terminal base 642, the external connect part 411 of the second input terminal 41B is exposed. A plurality of grooves 643 are formed so as to extend in the first direction x, between the first terminal base 641 and the second terminal base 642. As shown in FIG. 10 and FIG. 13, a pair of nuts 644 and a pair of intermediate members 645 are respectively provided inside the first terminal base 641 and the second terminal base 642. The pair of intermediate members 645 are located on the side of the insulation layer 11 in the thickness direction z with respect to the respective nuts 644, and in contact therewith. One of the intermediate members 645 supports the external connect part 421 and the intermediate part 423 of the first terminal part 42A. The other intermediate member 645 supports the external connect part 421 and the intermediate part 423 of the second terminal part 42B. A part of each of the pair of intermediate members 645 is exposed from the output terminal base 64. The pair of nuts 644 respectively correspond to the pair of connect holes 421A, formed in the first terminal part 42A and the second terminal part 42B. The fastening member such as a bolt, inserted in each of the pair of connect holes 421A, is screw-fitted with the corresponding nut 644.

The sealing resin 70 covers the plurality of semiconductor elements 31, as shown in FIG. 10 and FIG. 11. The sealing resin 70 is electrically insulative. The sealing resin 70 is, for example, formed of silicone gel. Alternatively, the sealing resin 70 may be an epoxy-based resin.

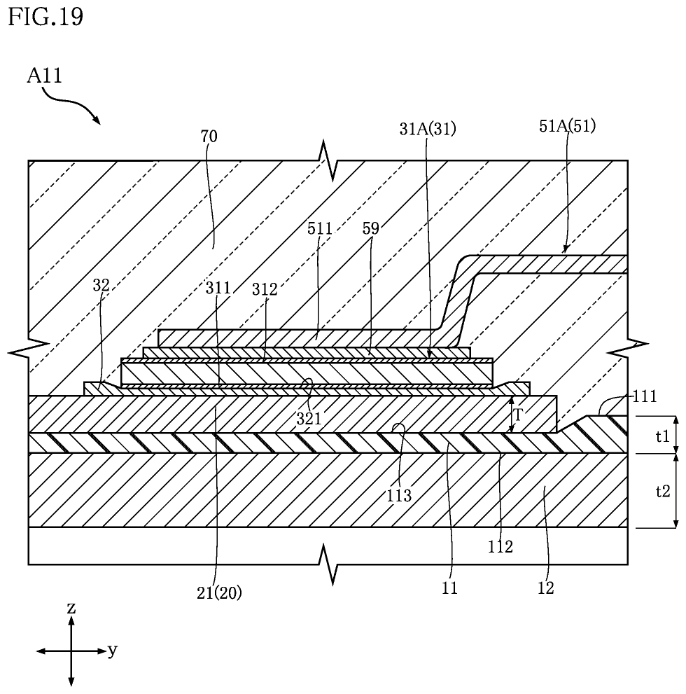

Referring now to FIG. 19, a semiconductor device A11, which is a variation of the semiconductor device A10, will be described hereunder. FIG. 19 illustrates the same position as FIG. 15.

As shown in FIG. 19, the insulation layer 11 includes a second recess 113, receding in the same direction as the first recess 321 of the buffer layer 32. The first recess 321 is overlapping with the second recess 113, as viewed in the thickness direction z. The second recess 113 is formed at the same time as the formation of the first recess 321. The second recess 113 is in contact with the sealing resin 70. The first recess 321 and the second recess 113 can be obtained, by applying a higher pressure than in the case of the semiconductor device A10 shown in FIG. 15, in the process of the solid-phase diffusion bonding of the element metal layer 311 of each of the plurality of semiconductor elements 31, to either of the first support layer 21 and the second support layer 22, via the buffer layer 32. In this case, it is important to make the thickness t1 of the insulation layer 11 equal or generally equal to the thickness T of the plurality of support layers 20, and to select a tough material to form the insulation layer 11.

Hereunder, the working and the advantageous effects of the semiconductor device A10 will be described.

The semiconductor device A10 includes the insulation layer 11, the support layer 20 located on the insulation layer 11 and containing a metal element in the composition, and the semiconductor element 31 bonded to the support layer 20. The semiconductor element 31 includes the element metal layer 311 opposed to the support layer 20. The solid-phase diffusion bonding layer 33 is interposed between the support layer 20 and the element metal layer 311. Accordingly, the bonding interface between the support layer 20 and the element metal layer 311 is constituted of the solid-phase diffusion bonding layer 33. Further, the insulation layer 11 is lower in Vickers hardness, than the support layer 20. With such configuration, the insulation layer 11 exhibits higher deformation performance than the support layer 20, when the element metal layer 311 is bonded to the support layer 20 by means of solid-phase diffusion, and therefore bending force exerted on the support layer 20, about the direction orthogonal to the thickness direction z, is reduced. Accordingly, the compression stress is evenly applied to the solid-phase diffusion bonding layer 33, which enhances the metal bond in the solid-phase diffusion bonding layer 33. As result, the solid-phase diffusion bonding layer 33 can exhibit stabilized heat dissipation performance, for a long period of time. Consequently, the semiconductor device A10 stabilizes the heat dissipation performance from the bonding interface between the support layer 20 and the semiconductor element 31, for a long period of time.

The semiconductor device A10 further includes the buffer layer 32, interposed between the support layer 20 and the element metal layer 311 of the semiconductor element 31. The buffer layer 32 is lower in Vickers hardness than the support layer 20. Such a configuration reduces the bending stress applied to each of the support layer 20 and the element metal layer 311, when the element metal layer 311 is bonded to the support layer 20 by means of solid-phase diffusion. Accordingly, the metal bond in the solid-phase diffusion bonding layer 33 is further enhanced. Consequently, the heat dissipation performance of the solid-phase diffusion bonding layer 33 is further improved. When the composition of the buffer layer 32 includes aluminum, the bending stress applied to each of the support layer 20 and the element metal layer 311 can be more effectively reduced.

The buffer layer 32 includes the first recess 321, receding toward the support layer 20. The element metal layer 311 of the semiconductor element 31 is overlapping with the first recess 321, as viewed in the thickness direction z. Such a configuration shows that a relatively high pressure was applied to the solid-phase diffusion bonding layer 33. Therefore, it can be easily confirmed visually, that the metal bond in the solid-phase diffusion bonding layer 33 has been further enhanced.

In the semiconductor device A11, the insulation layer 11 includes the second recess 113, receding to the same side as the first recess 321 of the buffer layer 32. The first recess 321 is overlapping with the second recess 113, as viewed in the thickness direction z. Such a configuration shows that a higher pressure was applied to the solid-phase diffusion bonding layer 33, than in the case of the semiconductor device A10.

It is preferable that the thickness of the insulation layer 11 is equal to or relatively smaller than the thickness of the support layer 20. Therefore, the bending force exerted on the support layer 20, about the direction orthogonal to the thickness direction z, can be more effectively reduced, when the element metal layer 311 of the semiconductor element 31 is bonded to the support layer 20 by means of solid-phase diffusion. It is preferable, from the viewpoint of effectively reducing the bending force exerted on the support layer 20, that the support layer 20 is between once as thick and 60 times as thick, both ends inclusive, as the insulation layer 11.

The element metal layer 311 of the semiconductor element 31 is electrically connected to the circuit formed on the semiconductor element 31. Accordingly, the element metal layer 311 corresponds to the electrode of the semiconductor element 31. In this case, a current runs in the solid-phase diffusion bonding layer 33, when the semiconductor device A10 is put to use. When the metal bond in the solid-phase diffusion bonding layer 33 is further enhanced, long-term fluctuation of the current running in the solid-phase diffusion bonding layer 33 is suppressed. Therefore, the current running in the bonding interface between the support layer 20 and the semiconductor element 31 can be stabilized, for a long period of time.

The semiconductor device A10 further includes the first input terminal 41A, electrically connected to the two first support layers 21, and the second input terminal 41B electrically connected to the plurality of second semiconductor elements 31B. The first input terminal 41A and the second input terminal 41B are located adjacent to each other. Accordingly, when a voltage is applied to the first input terminal 41A and the second input terminal 41B, mutual inductance is generated in the first input terminal 41A and the second input terminal 41B. Therefore, parasitic inductance in the semiconductor device A10 can be reduced.

The semiconductor device A10 further includes the heat dissipation layer 12, located on the opposite side of the support layer 20, across the insulation layer 11. The heat dissipation layer 12 is thicker than the insulation layer 11. Therefore, the heat transmitted from the semiconductor element 31 to the insulation layer 11, via the solid-phase diffusion bonding layer 33, can be efficiently released to outside of the semiconductor device A10.

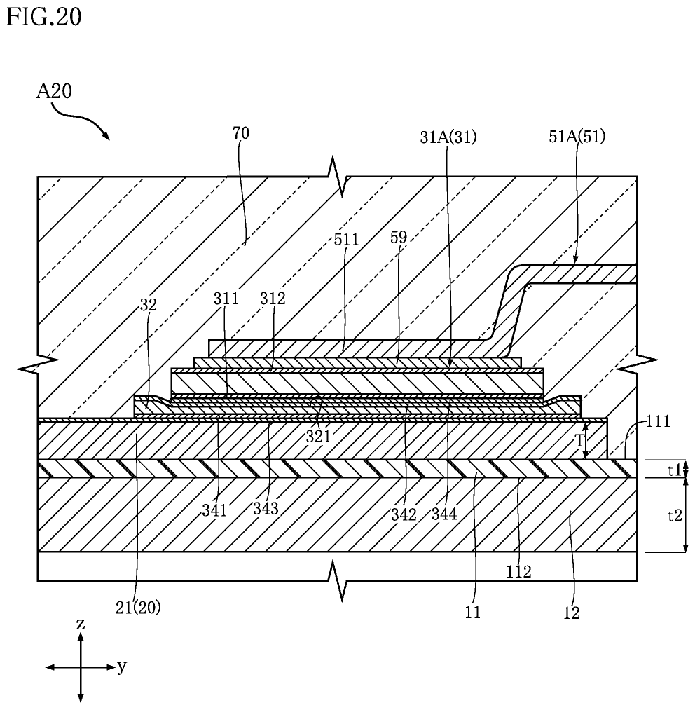

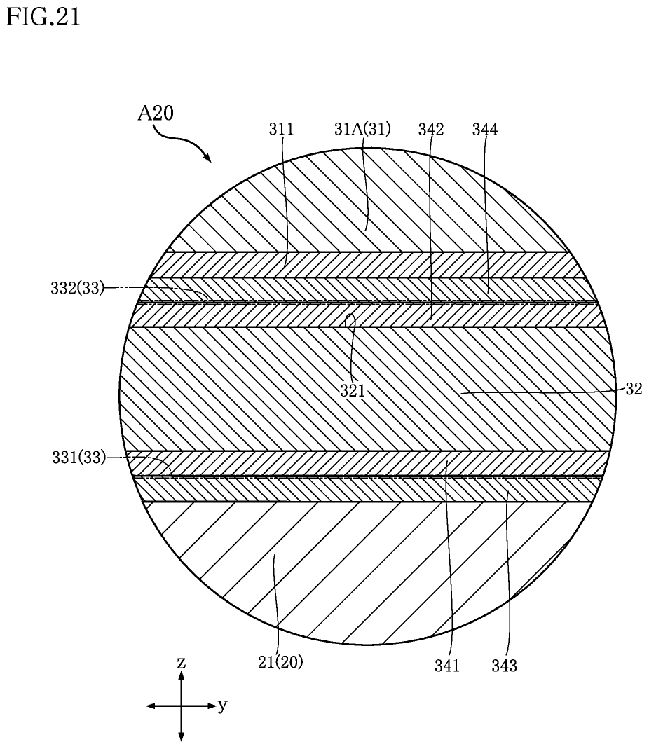

Referring to FIG. 20 and FIG. 21, a semiconductor device A20 according to a second embodiment of the present disclosure will be described hereunder. In these drawings, the elements same as or similar to those of the semiconductor device A10 are given the same numeral, and the description of such elements will not be repeated. Here, FIG. 20 represents the same position as FIG. 15 illustrating the semiconductor device A10.

The semiconductor device A20 is different from the semiconductor device A10 described above, in further including a first metal layer 341, a second metal layer 342, a third metal layer 343, and a fourth metal layer 344. FIG. and FIG. 21 each illustrate the configuration of a portion between the first support layer 21 of the plurality of support layers 20 and one of the plurality of first semiconductor elements 31A of the plurality of semiconductor element 31. In the semiconductor device A20, however, the configuration of the portion between the second support layer 22 of the plurality of support layers 20 and one of the plurality of second semiconductor elements 31B of the plurality of semiconductor elements 31 is the same as the configuration of the portion between the first support layer 21 and the first semiconductor element 31A. Therefore, the description of the semiconductor device A20 will be primarily focused on the configuration of the portion between the first support layer 21 and one of the plurality of first semiconductor elements 31A.

As shown in FIG. 20, the first metal layer 341 is interposed between the first support layer 21 and the buffer layer 32. The first metal layer 341 is in contact with the buffer layer 32. The composition of the first metal layer 341 includes, for example, silver (Ag). The second metal layer 342 is interposed between the buffer layer 32 and the element metal layer 311 of one of the plurality of first semiconductor elements 31A. The second metal layer 342 is in contact with the buffer layer 32. The composition of the second metal layer 342 includes, for example, silver. When the element metal layer 311 of the plurality of first semiconductor elements 31A is bonded to the first support layer 21, via the buffer layer 32 by means of solid-phase diffusion, the first metal layer 341 and the second metal layer 342 cover the buffer layer 32.

As shown in FIG. 20, the third metal layer 343 is interposed between the first support layer 21 and the first metal layer 341. The third metal layer 343 is in contact with the first support layer 21. The composition of the third metal layer 343 includes, for example, silver. When the element metal layer 311 of the plurality of first semiconductor elements 31A is bonded to the first support layer 21, via the buffer layer 32 by means of solid-phase diffusion, the third metal layer 343 covers the first support layer 21.

As shown in FIG. 20, the fourth metal layer 344 is interposed between the second metal layer 342 and the element metal layer 311 of one of the plurality of first semiconductor elements 31A. The fourth metal layer 344 is in contact with the element metal layer 311. The composition of the fourth metal layer 344 includes, for example, silver. When the element metal layer 311 of the plurality of first semiconductor elements 31A is bonded to the first support layer 21, via the buffer layer 32 by means of solid-phase diffusion, the fourth metal layer 344 covers one of the element metal layers 311.

As shown in FIG. 21, the first bonding layer 331 of the solid-phase diffusion bonding layer 33 is located along the interface between the first metal layer 341 and the third metal layer 343. The second bonding layer 332 of the solid-phase diffusion bonding layer 33 is located along the interface between the second metal layer 342 and the fourth metal layer 344.

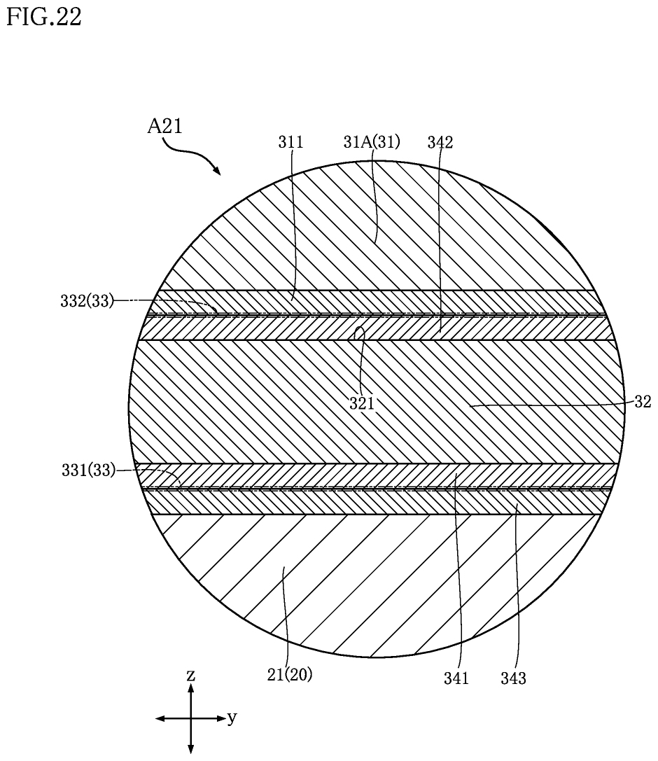

Referring now to FIG. 22, a semiconductor device A21, which is a variation of the semiconductor device A20, will be described hereunder. FIG. 22 represents the same position as FIG. 21.

As shown in FIG. 22, the semiconductor device A21 is without the fourth metal layer 344. In this case, the second bonding layer 332 of the solid-phase diffusion bonding layer 33 is located along the interface between the second metal layer 342 and the element metal layer 311 of one of the plurality of first semiconductor elements 31A.

The working and the advantageous effects of the semiconductor device A20 will be described hereunder.

The semiconductor device A20 includes the insulation layer 11, the support layer 20 located on the insulation layer 11 and contains a metal element in the composition, and the semiconductor element 31 bonded to the support layer 20. The semiconductor element 31 includes the element metal layer 311 opposed to the support layer 20. Between the support layer 20 and the element metal layer 311, the solid-phase diffusion bonding layer 33 is interposed. The insulation layer 11 is lower in Vickers hardness, than the support layer 20. Therefore, the semiconductor device A20 can also stabilize the heat dissipation performance of the bonding interface, interposed between the support layer 20 and the semiconductor element 31, for a long period of time. Further, since the semiconductor device A20 is configured similarly to the semiconductor device A10, the semiconductor device A20 also provides the same advantageous effects, as those provided by the semiconductor device A10.

The semiconductor device A20 further includes the first metal layer 341, the second metal layer 342, and the third metal layer 343. The first metal layer 341 and the second metal layer 342 are in contact with the buffer layer 32. The third metal layer 343 is in contact with the support layer 20. The composition of the first metal layer 341, the second metal layer 342, and the second metal layer 342 includes silver. In this case, the first bonding layer 331 of the solid-phase diffusion bonding layer 33 is located along the interface between the first metal layer 341 and the third metal layer 343. When the metal layers, both containing silver, are bonded to each other by means of solid-phase diffusion, relatively high bonding strength can be obtained. Therefore, the metal bond in the solid-phase diffusion bonding layer 33 can be further enhanced.

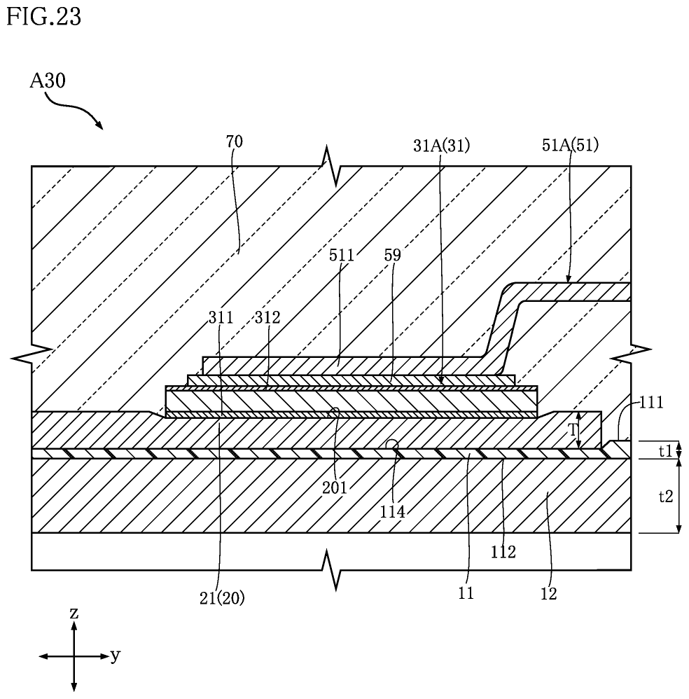

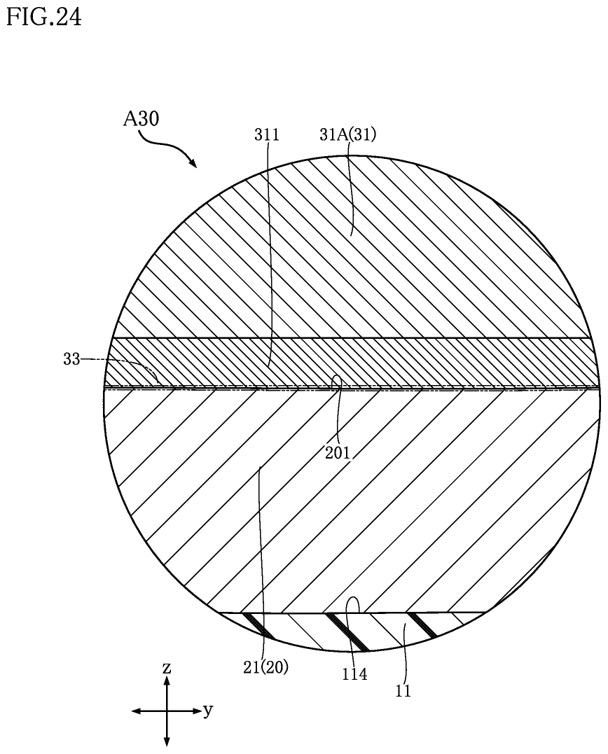

Referring to FIG. 23 and FIG. 24, a semiconductor device A30 according to a third embodiment of the present disclosure will be described hereunder. In these drawings, the elements same as or similar to those of the semiconductor device A10 are given the same numeral, and the description of such elements will not be repeated. Here, FIG. 23 represents the same position as FIG. 15 illustrating the semiconductor device A10.

The semiconductor device A30 is different from the semiconductor device A10, in not including the buffer layer 32. FIG. 23 and FIG. 24 each illustrate the configuration of the portion between the first support layer 21 of the plurality of support layers 20, and one of the plurality of first semiconductor elements 31A of the plurality of semiconductor elements 31. Here, in the semiconductor device A30 also, the configuration of the portion between the second support layer 22 of the plurality of support layers 20, and one of the plurality of second semiconductor elements 31B of the plurality of semiconductor elements 31, is the same as the configuration of the portion between the first support layer 21 and the first semiconductor element 31A. Therefore, the description of the semiconductor device A30 will also be primarily focused on the configuration of the portion between the first support layer 21 and one of the plurality of first semiconductor elements 31A.

As shown in FIG. 23, the element metal layer 311 of one of the plurality of first semiconductor elements 31A is in contact with the first support layer 21. The composition of the element metal layer 311 includes, for example, silver. As shown in FIG. 24, the solid-phase diffusion bonding layer 33 is located along the interface between the first support layer 21 and the element metal layer 311. In the semiconductor device A30, the solid-phase diffusion bonding layer 33 is without the first bonding layer 331 and the second bonding layer 332.

As shown in FIG. 23, the first support layer 21 includes a third recess 201 receding toward the insulation layer 11. The element metal layer 311 of one of the plurality of first semiconductor elements 31A is overlapping with the third recess 201, as viewed in the thickness direction z. The third recess 201 is a vestige resulting from the solid-phase diffusion bonding between the element metal layer 311 of the corresponding first semiconductor element 31A and the first support layer 21. Further, the third recess 201 is also formed in the second support layer 22, as the vestige resultant from the solid-phase diffusion bonding between the element metal layer 311 of one of the plurality of second semiconductor elements 31B and the second support layer 22.

As shown in FIG. 23, the insulation layer 11 includes a fourth recess 114, receding to the same side as the third recess 201 of the first support layer 21. The third recess 201 is overlapping with the fourth recess 114, as viewed in the thickness direction z. The fourth recess 114 is formed at the same time as the third recess 201. The third recess 201 and the fourth recess 114 may be also formed in the semiconductor device A10. The condition that allows the formation of the mentioned recesses, is that the peripheral edge of the buffer layer 32 overlapping with one of the plurality of semiconductor elements 31, as viewed in the thickness direction z, coincides with the peripheral edge of the corresponding semiconductor element 31, or is surrounded thereby.

As shown in FIG. 23, the sealing resin 70 is in contact with the third recess 201 in the first support layer 21 and the fourth recess 114 in the insulation layer 11.

The working and the advantageous effects of the semiconductor device A30 will be described hereunder.

The semiconductor device A30 includes the insulation layer 11, the support layer 20 located on the insulation layer 11 and containing a metal element in the composition, and the semiconductor element 31 bonded to the support layer 20. The semiconductor element 31 includes the element metal layer 311 opposed to the support layer 20. The solid-phase diffusion bonding layer 33 is interposed between the support layer 20 and the element metal layer 311. The insulation layer 11 is lower in Vickers hardness, than the support layer 20. Therefore, the semiconductor device A30 can also stabilize the heat dissipation performance of the bonding interface, interposed between the support layer 20 and the semiconductor element 31, for a long period of time. Further, since the semiconductor device A30 is configured similarly to the semiconductor device A10, the semiconductor device A30 also provides the same advantageous effects, as those provided by the semiconductor device A10.

In the semiconductor device A30, the composition of the element metal layer 311 of the semiconductor element 31 includes silver. In this case, when the element metal layer 311 is bonded to the support layer 20 by means of solid-phase diffusion, the element metal layer 311 serves as the substitute for the buffer layer 32. Therefore, the buffer layer 32 can be excluded.

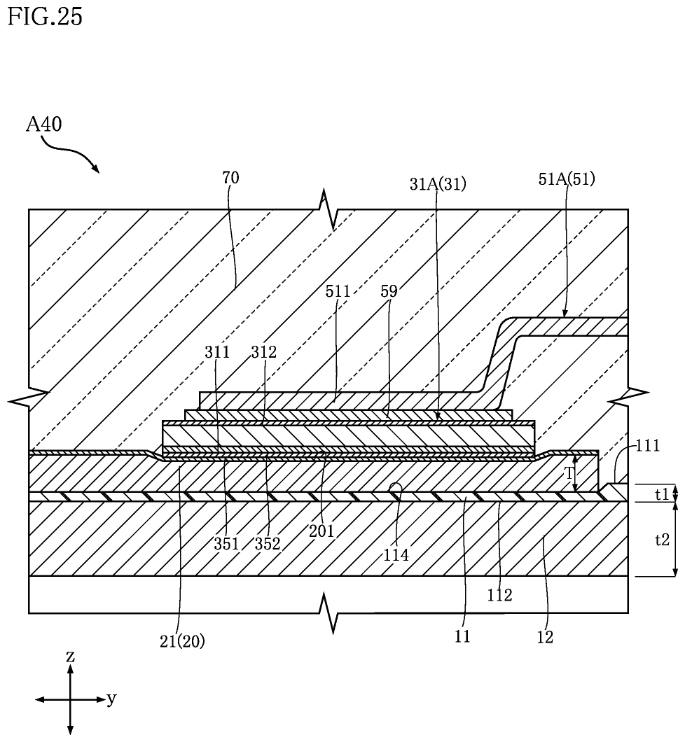

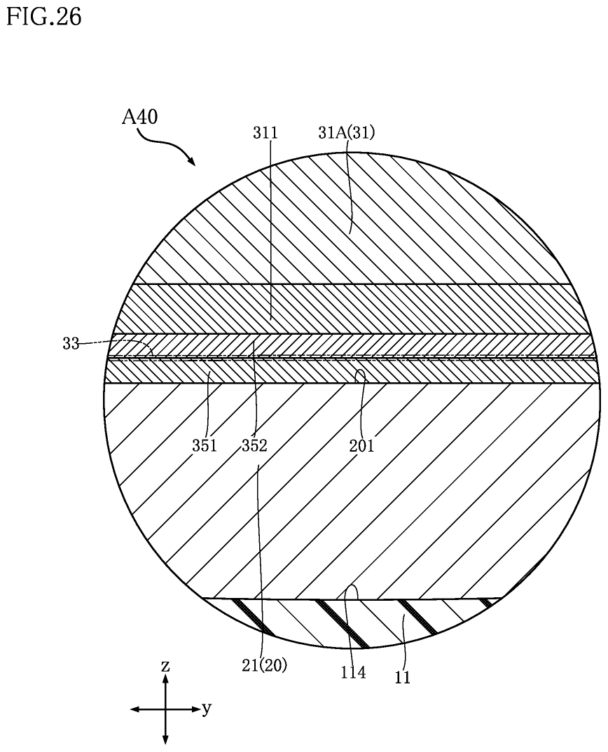

Referring to FIG. 25 and FIG. 26, a semiconductor device A40 according to a fourth embodiment of the present disclosure will be described hereunder. In these drawings, the elements same as or similar to those of the semiconductor device A10 are given the same numeral, and the description of such elements will not be repeated. Here, FIG. 25 represents the same position as FIG. 15 illustrating the semiconductor device A10.

The semiconductor device A40 is different from the semiconductor device A30, in further including a lower metal layer 351 and an upper metal layer 352. FIG. 25 and FIG. 26 each illustrate the configuration of the portion between the first support layer 21 of the plurality of support layers 20, and one of the plurality of first semiconductor elements 31A of the plurality of semiconductor elements 31. Here, in the semiconductor device A40 also, the configuration of the portion between the second support layer 22 of the plurality of support layers 20, and one of the plurality of second semiconductor elements 31B of the plurality of semiconductor elements 31, is the same as the configuration of the portion between the first support layer 21 and the first semiconductor element 31A. Therefore, the description of the semiconductor device A40 will also be primarily focused on the configuration of the portion between the first support layer 21 and one of the plurality of first semiconductor elements 31A.

As shown in FIG. 25, the lower metal layer 351 is interposed between the first support layer 21 and the element metal layer 311 of one of the plurality of first semiconductor elements 31A. The lower metal layer 351 is in contact with the first support layer 21. The composition of the lower metal layer 351 includes, for example, silver. When the element metal layer 311 of the plurality of first semiconductor elements 31A is bonded to the first support layer 21 by means of solid-phase diffusion, the lower metal layer 351 covers the first support layer 21.

As shown in FIG. 25, the upper metal layer 352 is interposed between the lower metal layer 351 and the element metal layer 311 of one of the plurality of first semiconductor elements 31A. The upper metal layer 352 is in contact with the element metal layer 311. The composition of the upper metal layer 352 includes, for example, silver. When the element metal layer 311 of the plurality of first semiconductor elements 31A is bonded to the first support layer 21 by means of solid-phase diffusion, the upper metal layer 352 covers one of the element metal layers 311. As shown in FIG. 26, the solid-phase diffusion bonding layer 33 is located along the interface between the lower metal layer 351 and the upper metal layer 352.

The working and the advantageous effects of the semiconductor device A40 will be described hereunder.

The semiconductor device A40 includes the insulation layer 11, the support layer 20 located on the insulation layer 11 and containing a metal element in the composition, and the semiconductor element 31 bonded to the support layer 20. The semiconductor element 31 includes the element metal layer 311 opposed to the support layer 20. The solid-phase diffusion bonding layer 33 is interposed between the support layer 20 and the element metal layer 311. The insulation layer 11 is lower in Vickers hardness, than the support layer 20. Therefore, the semiconductor device A40 can also stabilize the heat dissipation performance of the bonding interface, interposed between the support layer 20 and the semiconductor element 31, for a long period of time. Further, since the semiconductor device A40 is configured similarly to the semiconductor device A10, the semiconductor device A40 also provides the same advantageous effects, as those provided by the semiconductor device A10.

The semiconductor device A40 further includes the lower metal layer 351 and the upper metal layer 352. The lower metal layer 351 is in contact with the support layer 20. The upper metal layer 352 is in contact with the element metal layer 311 of the semiconductor elements 31. The composition of the lower metal layer 351 and the upper metal layer 352 includes silver. In this case, the solid-phase diffusion bonding layer 33 is located along the interface between the lower metal layer 351 and the upper metal layer 352. Accordingly, the semiconductor device A40 also provides the same advantageous effects, as those provided by the semiconductor device A20, and therefore the metal bond in the solid-phase diffusion bonding layer 33 can be further enhanced.

The present disclosure is not limited to the foregoing embodiments. The specific configuration of each of the elements according to the present disclosure may be modified in various manners. For example,

The present disclosure encompasses embodiments according to the following clauses.
Clause 1
A semiconductor device including:
an insulation layer;
a support layer located on the insulation layer, and containing a metal; and
a semiconductor element bonded to the support layer,
in which the semiconductor element includes an element metal layer facing the support layer,
a solid-phase diffusion bonding layer is interposed between the support layer and the element metal layer, and
the insulation layer is lower in Vickers hardness than the support layer.
Clause 2
The semiconductor device according to clause 1,
in which the insulation layer contains a resin.
Clause 3
The semiconductor device according to clause 2,
in which the metal includes copper.
Clause 4
The semiconductor device according to any one of appendices 1 to 3, further including a buffer layer interposed between the support layer and the element metal layer,
in which the solid-phase diffusion bonding layer includes a first bonding layer located between the support layer and the buffer layer, and a second bonding layer located between the buffer layer and the element metal layer, and
the buffer layer is lower in Vickers hardness than the support layer.
Clause 5
The semiconductor device according to clause 4,
in which the buffer layer contains aluminum.
Clause 6
The semiconductor device according to clause 4 or 5, further including:
a first metal layer interposed between the support layer and the buffer layer;
a second metal layer interposed between the buffer layer and the element metal layer; and
a third metal layer interposed between the support layer and the first metal layer,
in which the first metal layer and the second metal layer are in contact with the buffer layer,
the third metal layer is in contact with the support layer,
the first bonding layer is located along an interface between the first metal layer and the third metal layer, and
the second bonding layer is located between the second metal layer and the element metal layer.
Clause 7
The semiconductor device according to clause 6,
in which the first metal layer, the second metal layer, and the third metal layer each contain silver.
Clause 8
The semiconductor device according to clause 6 or 7, further including a fourth metal layer interposed between the second metal layer and the element metal layer,
in which the fourth metal layer is in contact with the element metal layer, and
the second bonding layer is located along an interface between the second metal layer and the fourth metal layer.
Clause 9
The semiconductor device according to any one of appendices 4 to 8,
in which the buffer layer includes a first recess receding toward the support layer, and
the element metal layer is overlapping with the first recess, as viewed in a thickness direction of the insulation layer.
Clause 10
The semiconductor device according to clause 9,
in which the insulation layer includes a second recess receding in a same direction as the first recess, and
the first recess is overlapping with the second recess, as viewed in the thickness direction.
Clause 11
The semiconductor device according to clause 9 or 10, further including a sealing resin covering the semiconductor element,
in which the sealing resin is in contact with the first recess.
Clause 12
The semiconductor device according to any one of appendices 1 to 3,
in which the element metal layer contains silver.
Clause 13
The semiconductor device according to clause 12, further including a lower metal layer interposed between the support layer and the element metal layer; and
an upper metal layer interposed between the lower metal layer and the element metal layer,
in which the lower metal layer is in contact with the support layer,
the upper metal layer is in contact with, the element metal layer, and
the solid-phase diffusion bonding layer is located along an interface between the lower metal layer and the upper metal layer.
Clause 14
The semiconductor device according to any one of appendices 1 to 13,
in which the insulation layer is as thick as or thinner than the support layer.
Clause 15
The semiconductor device according to clause 14,
in which the support layer is between once as thick and 60 times as thick, both ends inclusive, as the insulation layer.
Clause 16
The semiconductor device according to any one of appendices 1 to 15, further including a heat dissipation layer located on an opposite side of the support layer, across the insulation layer,
in which the heat dissipation layer is thicker than the insulation layer.
Clause 17
The semiconductor device according to any one of appendices 1 to 16,
in which the element metal layer is electrically connected to a circuit formed on the semiconductor element.

### REFERENCE NUMERALS

A10, A20, A30, A40: semiconductor device 11: insulation layer
111: obverse face 112: reverse face 113: second recess
114: fourth recess 12: heat dissipation layer 20: support layer
201: third recess 21: first support layer 211: first pad part
22: second support layer 221: second pad part
23: third support layer
231: third pad part 24: gate wiring
241: first gate wiring 242: second gate wiring
25: detection wiring 251: first detection wiring
252: second detection wiring 26: pad 31: semiconductor element
31A: first semiconductor element 31B: second semiconductor element
311: element metal layer 312: first electrode
313: second electrode
32: buffer layer 32: first recess
33: solid-phase diffusion bonding layer
331: first bonding layer 332: second bonding layer
341: first metal layer
342: second metal layer 343: third metal layer
344: fourth metal layer
351: lower metal layer 352: upper metal layer 39: thermistor
41: input terminal 41A: first input terminal
41B: second input terminal
411: external connect part 411A: connect hole
412: internal connect part
413: intermediate part 413A: base portion 413B: upright portion
42: output terminal 42A: first terminal part
42B: second terminal part
421: external connect part 421A: connect hole
422: internal connect part
423: intermediate part 423A: base portion 423B: upright portion
43: gate terminal 43A: first gate terminal
43B: second gate terminal 44: detect terminal
44A: first detect terminal
44B: second detect terminal 45: input current detect terminal
46: thermistor terminal 51: conduction member
51A: first conduction member
51B: second conduction member 511: first bonding portion
512: second bonding portion
521: first gate wire 522: second gate wire
531: first detect wire 532: second detect wire
54: input current detect wire 55: thermistor wire
59: bonding layer 60: case 611: first sidewall
612: second sidewall 62: mounting base 621: mounting hole
63: input terminal base 631: first terminal base
632: second terminal base
633: groove 634: nut 635: intermediate member
64: output terminal base 641: first terminal base
642: second terminal base
643: groove 644: nut 645: intermediate member
70: sealing resin T, t1, t2: thickness
z: thickness direction x: first direction y: second direction

1. A semiconductor device comprising:
an insulation layer;
a support layer located on the insulation layer and containing a metal; and
a semiconductor element bonded to the support layer,
wherein the semiconductor element includes an element metal layer facing the support layer,
a solid-phase diffusion bonding layer is interposed between the support layer and the element metal layer, and
the insulation layer is lower in Vickers hardness than the support layer.

2. The semiconductor device according to claim 1, wherein the insulation layer contains a resin.

3. The semiconductor device according to claim 2, wherein the metal includes copper.

4. The semiconductor device according to claim 1, further comprising a buffer layer interposed between the support layer and the element metal layer,
wherein the solid-phase diffusion bonding layer includes a first bonding layer located between the support layer and the buffer layer, and a second bonding layer located between the buffer layer and the element metal layer, and
the buffer layer is lower in Vickers hardness than the support layer.

5. The semiconductor device according to claim 4, wherein the buffer layer contains aluminum.

6. The semiconductor device according to claim 4, further comprising:
a first metal layer interposed between the support layer and the buffer layer;
a second metal layer interposed between the buffer layer and the element metal layer; and
a third metal layer interposed between the support layer and the first metal layer,
wherein the first metal layer and the second metal layer are in contact with the buffer layer,
the third metal layer is in contact with the support layer,
the first bonding layer is located along an interface between the first metal layer and the third metal layer, and
the second bonding layer is located between the second metal layer and the element metal layer.

7. The semiconductor device according to claim 6, wherein the first metal layer, the second metal layer, and the third metal layer each contain silver.

8. The semiconductor device according to claim 6, further comprising a fourth metal layer interposed between the second metal layer and the element metal layer,
wherein the fourth metal layer is in contact with the element metal layer, and
the second bonding layer is located along an interface between the second metal layer and the fourth metal layer.

9. The semiconductor device according to claim 4, wherein the buffer layer includes a first recess receding toward the support layer, and
the element metal layer is overlapping with the first recess, as viewed in a thickness direction of the insulation layer.

10. The semiconductor device according to claim 9, wherein the insulation layer includes a second recess receding in a same direction as the first recess, and
the first recess is overlapping with the second recess, as viewed in the thickness direction.

11. The semiconductor device according to claim 9, further comprising a sealing resin covering the semiconductor element,
wherein the sealing resin is in contact with the first recess.

12. The semiconductor device according to claim 1, wherein the element metal layer contains silver.

13. The semiconductor device according to claim 12, further comprising a lower metal layer interposed between the support layer and the element metal layer; and
an upper metal layer interposed between the lower metal layer and the element metal layer,
wherein the lower metal layer is in contact with the support layer,
the upper metal layer is in contact with, the element metal layer, and
the solid-phase diffusion bonding layer is located along an interface between the lower metal layer and the upper metal layer.

14. The semiconductor device according to claim 1, wherein the insulation layer is as thick as or thinner than the support layer.

15. The semiconductor device according to claim 14, wherein the support layer is between once as thick and 60 times as thick, both ends inclusive, as the insulation layer.

16. The semiconductor device according to claim 1, further comprising a heat dissipation layer located on an opposite side of the support layer, across the insulation layer,
wherein the heat dissipation layer is thicker than the insulation layer.

17. The semiconductor device according to claim 1,
wherein the element metal layer is electrically connected to the support layer, and a circuit formed on the semiconductor element.
